(19) United States
(12) Patent Application Publication
(10) Pub. No.: US 2025/0201779 A1
(43) Pub. Date: Jun. 19, 2025

(54) TILING DISPLAY DEVICE

(71) Applicant: LG Display Co., Ltd., Seoul (KR)

(72) Inventors: Young Tae KIM, Paju-si (KR); Chang Mo YANG, Paju-si (KR)

(21) Appl. No.: 18/936,138

(22) Filed: Nov. 4, 2024

(30) Foreign Application Priority Data
Dec. 18, 2023 (KR) 10-2023-0184672

(51) Int. Cl. H01L 25/075; H01L 33/50

(52) U.S. Cl. CPC H01L 25/0753; H10H 20/851

(57) ABSTRACT

A tiling display device is disclosed. The tiling display device according to the specification includes a plurality of pixels disposed on a display panel, a first pixel area including a first pixel and second pixel neighboring to each other, and a second pixel area including the first pixel and a third pixel neighboring to each other. The sum of brightness for each color of any one of two pixels selected from the group consisting of the first pixel, the second pixel, and the third pixel is larger than the sum of brightness for each color of each of the pixels between which a distance is relatively smaller than a distance between the two selected pixels. According to the tiling display device according to the specification, it is possible to improve image quality and visibility and prevent the degradation of color reproducibility.

### CROSS-REFERENCE TO RELATED APPLICATION

This application claims priority to and the benefit of Korean Patent Application No. 10-2023-0184672, filed on Dec. 18, 2023, the disclosure of which is incorporated herein by reference in its entirety.

### BACKGROUND

### Technical Field

The present disclosure relates to a tiling display device.

### Description of the Related Art

Organic light emitting diode (OLED) display devices reproduce images by allowing OLEDs disposed in each pixel to emit light according to input image signals. Since an OLED display device has a fast response time, high luminous efficiency and brightness, and a wide viewing angle and may express a black gradation in perfect black, the OLED display device has an excellent contrast ratio and an excellent color gamut. The OLED display device does not require a backlight unit.

Recently, display devices using light emitting diodes (LEDs), which are inorganic light emitting elements, as light emitting elements for pixels are attracting attention as next-generation display devices. Since an LED is made of an inorganic material, the LED does not require a separate encapsulation layer for protecting an organic material from moisture and has superior reliability and longer lifetime than the OLED. In addition, the LED has a fast lighting speed, excellent luminous efficiency, and impact resistance.

When a display device is driven, the quality of images reproduced on a display panel is degraded when the brightness of the display panel and/or the distribution of peak wavelengths of each light emitting element are not uniform. For example, when the distance between adjacent pixels with respect to a boundary which is present between display panel units increase or decrease, a brightness deviation of the overall display panels may occur. Alternatively or additionally, when the peak wavelengths of the adjacent pixels with respect to the boundary are not uniform, color reproducibility can be degraded.

### BRIEF SUMMARY

The present disclosure is directed to providing a display device in which a brightness deviation and/or degradation of color reproducibility caused by coupling in units of display panels on a screen of a tiling display device are prevented and image quality is improved.

The technical features of the present specification are not limited to those described above, and other technical features that are not mentioned will be able to be clearly understood by those skilled in the art from the following description.

A tiling display device according to the specification includes a plurality of pixels disposed on a display panel, a first pixel area including a first pixel and a second pixel neighboring to each other, and a second pixel area including the first pixel and a third pixel neighboring to each other, wherein a brightness of the first color of the first pixel area is substantially the same as a brightness of the first color of the second pixel area, and a sum of brightness for each color of any one of two pixels selected from the group consisting of the first pixel, the second pixel, and the third pixel is larger than a sum of brightness for each color of each of two pixels between which a distance is relatively smaller than a distance between the two selected pixels.

A tiling display device according to the specification includes a plurality of pixels disposed on a display panel, a first pixel area including a first pixel and a second pixel neighboring to each other, and a second pixel area including the first pixel and a third pixel neighboring to each other, wherein a brightness of a first color of the first pixel area is substantially the same as a brightness of the first color of the second pixel area, and a sum of brightness for each color of any one of two pixels selected from the group consisting of the first pixel, the second pixel, and the third pixel is smaller than a sum of brightness for each color of each of two pixels between which a distance is relatively larger than a distance between the two selected pixels.

A tiling display device according to the specification includes a first pixel including a 1-1 sub-pixel and a 1-2 sub-pixel that emit the same light in a wavelength band of a first color, and a second pixel disposed to be spaced apart from the first pixel and including a 2-1 sub-pixel and a 2-2 sub-pixel that emit the same light in the wavelength band of the first color, wherein a first pattern in which the 1-1 sub-pixel and the 2-2 sub-pixel are turned on and the 1-2 sub-pixel and the 2-1 sub-pixel are turned off and a second pattern in which the 1-1 sub-pixel and the 2-2 sub-pixel are turned off and the 1-2 sub-pixel and the 2-1 sub-pixel are turned on appear alternately in time.

A tiling display device according to the specification includes a first pixel including a 1-1 sub-pixel and a 1-2 sub-pixel that emit light in a wavelength band of the same color, and a second pixel disposed to be spaced apart from the first pixel and including a 2-1 sub-pixel and a 2-2 sub-pixel that emit light in a wavelength band of the same color, wherein a brightness of a first color of the first pixel is substantially the same as a brightness of the first color of the second pixel, and the 1-1 sub-pixel, the 1-2 sub-pixel, and the 2-1 sub-pixel are turned on, and the 2-2 sub-pixel is turned off.

A tiling display device according to the specification includes a first pixel including a 1-1 sub-pixel and a 1-2 sub-pixel that emit light in a wavelength band of the same color, and a second pixel disposed to be spaced apart from the first pixel and including a 2-1 sub-pixel and a 2-2 sub-pixel that emit light in a wavelength band of the same color, wherein a brightness of a first color of the first pixel is substantially the same as a brightness of the first color of the second pixel, and the 1-1 sub-pixel, the 1-2 sub-pixel, the 2-1 sub-pixel, and the 2-2 sub-pixel are turned on.

### BRIEF DESCRIPTION OF THE SEVERAL VIEWS OF THE DRAWINGS

FIG. 1 is a block diagram schematically showing a display device according to an embodiment.

FIG. 2 is a perspective view showing a tiling display device according to some embodiments.

FIG. 3 is a plan view showing the tiling display device according to some embodiments.

FIG. 4 is a plan view showing a pixel according to some embodiments.

FIG. 5 is a schematic graph showing luminous intensity distribution graphs according to wavelength bands of blue, green, and red light emitting elements.

FIGS. 6 and 7 are schematic graphs showing luminous intensity distribution graphs according to wavelength bands of the red light emitting element.

FIG. 8 is a schematic graph showing a luminous intensity distribution graph of a main light emitting element, a luminous intensity distribution graph of an auxiliary light emitting element, and a luminous intensity distribution graph of a pixel including the main light emitting element and the auxiliary light emitting element.

FIG. 9 is a partially enlarged view of the tiling display device according to some embodiments.

(a) and (b) of FIG. 10 are graphs showing brightness in an X direction in the tiling display device.

(c) and (d) of FIG. 10 are graphs showing brightness in a Y direction in the tiling display device.

(a) and (b) of FIG. 11 are graphs showing a change in brightness in the X direction in the tiling display device according to some embodiments.

(c) and (d) of FIG. 11 are graphs showing a change in brightness in the Y direction in the tiling display device according to some embodiments.

FIGS. 12A and 12B are partially enlarged views for describing a dark spot compensation of the tiling display device according to some embodiments.

FIG. 13 is a partially enlarged view for describing bright spot compensation of the tiling display device according to some embodiments.

FIG. 14 is a flowchart for describing a dark spot and bright spot compensation algorithm of the tiling display device according to some embodiments.

FIGS. 15A and 15B are partially enlarged views showing light amount ratios of sub-pixels included in adjacent pixel blocks.

FIG. 16 is a graph for describing a condition in which flicker is invisible.

FIGS. 17A, 17B, 18A and 18B are partially enlarged views showing light amount ratios of sub-pixels.

FIG. 19 is a partially enlarged view showing light amount ratios of sub-pixels. FIGS. 20 and 21 are partially enlarged views showing light amount ratios of sub-pixels.

FIG. 22 is a partially enlarged view showing light amount ratios of sub-pixels.

FIGS. 23 and 24 are partially enlarged views showing light amount ratios of sub-pixels.

### DETAILED DESCRIPTION

Advantages and features of the present specification and methods for achieving them will become clear with reference to embodiments described below in detail in conjunction with the accompanying drawings. The present disclosure is not limited to some embodiments disclosed below but can be implemented in various different forms, these embodiments are merely provided to make the disclosure of the present disclosure complete and fully inform those skilled in the art to which the present disclosure pertains of the scope of the present disclosure.

In describing the present disclosure, when it is determined that the detailed description of a related known technology may unnecessarily obscure the gist of the present disclosure, detailed description thereof will be omitted.

When the terms “comprises,” “includes,” “has,” and “consists of” described in the present specification are used, other parts may be added unless “only” is used. When a component is expressed in the singular, it can be construed as a plurality of components unless specifically stated otherwise.

When the position relationship and interconnection relationship between two components, such as “on,” “above,” “under,” “next to,” “connected or coupled,” “crossing or intersecting,” or the like described, one or more other components may be interposed between the components unless the term “immediately” or “directly” is described.

When the temporal relationship is described using the term “after,” “subsequently,” “then,” “before,” or the like, it may include a non-consecutive case unless the term “immediately” or “directly” is used.

Although the term “first,” “second,” or the like may be used to distinguish components, functions or structures of the components are not limited by the ordinal number or component name added to the front of the component.

The following embodiments may be partially or fully coupled or combined, and various technological interworking and driving are possible. Some embodiments may be implemented independently of each other and implemented together in the associated relationship.

In addition, terms (including technical and scientific terms) used in embodiments of the present specification may be construed as meaning that may be generally understood by those skilled in the art to which the present specification pertains unless explicitly specifically defined and described, and the meanings of the commonly used terms, such as terms defined in a dictionary, may be construed in consideration of contextual meanings of related technologies.

Hereinafter, embodiments of the present disclosure will be described in detail with reference to the accompanying drawings.

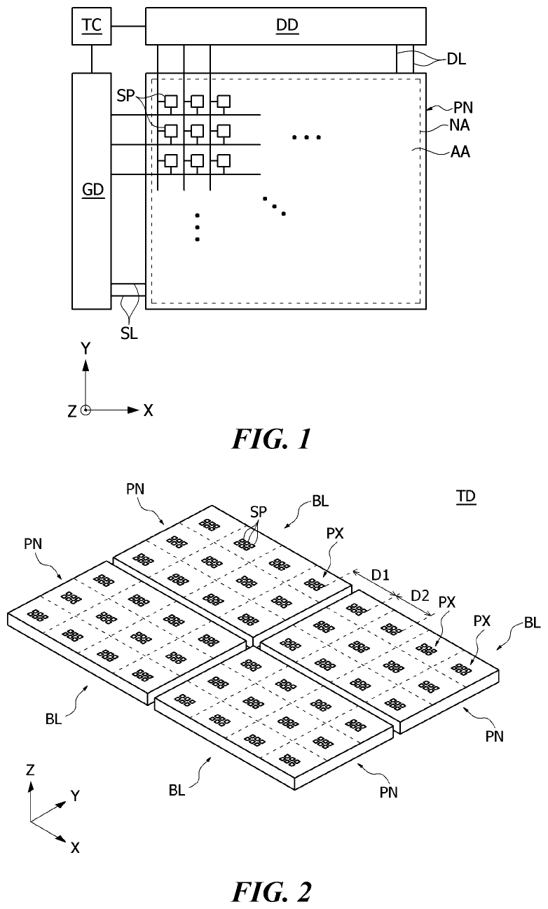

Referring to FIG. 1, a display device includes a display panel PN in which a plurality of pixels are disposed on a display area AA, and display panel driving circuits for driving pixels.

The display panel PN may be a panel with a rectangular structure having a length in an X-axis direction, a width in a Y-axis direction, and a thickness in a Z-axis direction. However, the display panel is not limited thereto and may be a panel with a square structure in which the length in the X-axis direction and a length in the Y-axis direction are the same. The pixels include a plurality of sub-pixels SP with different colors. The display area AA in which input images are displayed on the display panel PN may be a screen visible on a front surface of the display panel PN.

The display panel driving circuit includes a data driving unit DD, a gate driving unit GD, and a timing controller TC for controlling the gate driving unit GD and the data driving unit DD.

The input images are displayed on the sub-pixels SP disposed in the display area AA of the display panel PN. Each of the sub-pixels SP includes a light emitting element and a pixel circuit for driving the light emitting element. The light emitting element may be a light emitting diode (LED) or a micro-LED.

A plurality of scan lines SL and a plurality of data lines DL are disposed to intersect each other on the display panel PN. Each of the sub-pixels SP is connected to the scan line SL and the data line DL. Power lines omitted in FIG. 1 may be connected to the sub-pixels SP.

A non-display area NA may be disposed outside the display area AA in the display panel PN.

The gate driving unit GD supplies a scan signal to the scan lines SL in response to a gate control signal provided from the timing controller TC. The gate driving unit GD may be at least disposed on the non-display area NA of the display panel PN as shown in FIG. 1 or disposed on the display area AA (not shown).

The data driving unit DD converts image data received from the timing controller TC into a gamma compensation voltage in response to data control signals provided from the timing controller TC and outputs data voltages. The data voltages output from the data driving unit DD are supplied to the data lines DL.

The timing controller TC arranges the image data input from the outside and supplies the arranged image data to the data driving unit DD. The timing controller TC may generate a gate control signal and data control signal based on timing signals, which are synchronized with the input image signal, such as a dot clock signal, a data enable signal, and horizontal/vertical synchronization signals. The timing controller TC supplies the gate control signal to the gate driving unit GD and supplies the data control signal to the data driving unit DD to control operation timings of the gate driving unit GD and the data driving unit DD.

The timing controller TC may include a compensation unit (not shown). The compensation unit may detect brightness deviation which occurs between a boundary between a plurality of coupled display panels PN and the inside of the display panel PN or distribution and/or deviation of peak wavelengths at the boundary.

Target luminance deviation or peak wavelength distribution plot embedded in the timing controller TC can be implemented as a look-up table (LUT) and stored in a memory connected to the timing controller TC. The compensation unit may compensate pixel data to be written in each of the sub-pixels or determine a driving method. Specifically, the compensation unit may determine how much pixel data should be compensated for each sub-pixel or how it should be driven based on the target luminance deviation and/or peak wavelength distribution plot of the LUT and detected data for each sub-pixel.

Link lines and pad electrodes for transmitting signals to the sub-pixel SP of the display area AA may be disposed in the non-display area NA. In addition, at least one of a gate driver IC in which circuits of the gate driving unit GD are integrated and a data driver IC in which circuits of the data driving unit DD are integrated may be disposed in the non-display area NA. The non-display area NA may include a back surface of the display panel PN, that is, a back surface without sub-pixels SP. The non-display area NA can be reduced to be invisible when images are displayed on the display panel PN.

The display panel driving circuit may be connected to the display panel PN in any of various ways. For example, the gate driving unit GD may be disposed on the non-display area NA in a gate in panel (GIP) method and disposed between the sub-pixels SP in the display area AA in a gate in active area (GIA) method. For example, the data driving unit DD and the timing controller TC may be formed on a separate flexible film and a printed circuit board (PCB) and electrically connected to the display panel PN by bonding terminals of a flexible film to the pad electrodes formed in the non-display area NA of the display panel PN. The flexible film bonded to the display panel PN may be connected to the PCB on which circuit elements are mounted and lines are formed.

A plurality of display modules can be implemented as a large-screen tiling display device by being coupled on a flat surface. The display modules can be implemented as a single display device and implemented as the large-screen tiling display device through a combination of the plurality of display modules. Each of the display modules may include the display panel PN, the driving circuit of the display panel PN, and circuit components and module cover members coupled to the rear surface of the display panel PN.

Referring to FIG. 2, a large-screen tiling display device TD includes a plurality of display modules disposed on an XY plane. Each of the display modules includes the display panel PN for reproducing the input images. When the non-display area NA is reduced at a front edge of each display panel PN, a large screen image without visible seam between neighboring display panels PN can be reproduced.

The display panels PN may be assembled on the flat surface so that a distance D1 between an outermost pixel PX of one display panel PN and an outermost pixel PX of another display panel PN adjacent to the one display panel PN is substantially the same as a distance D2 between neighboring pixels PX in the display area AA of the display panel PN. As a result, since the distances D1 and D2 between the pixels PX are the same throughout a large-screen display area of the tiling display device TD, the seam area is invisible.

In the tiling display device TD, the plurality of display modules may share one timing controller TC. A host system may be connected to a plurality of timing controllers TC to transmit image signals to be reproduced on all display panels PN which implement the large screen of the tiling display device TD to the timing controllers TC and may synchronize the timing controllers TC.

In the tiling display device TD, the display panels PN may be coupled in units of blocks BL. In the drawing, for convenience of description, the display device TD is shown as having four blocks BL tiled, but by applying the same, additional blocks BL extending in the X and/or Y directions may be coupled to form the large-screen tiling display device TD.

In addition, the tiling display device TD may have a honeycomb structure or delta structure other than a structure in which the rectangular display panels PN shown in FIG. 2 are coupled.

In an embodiment, each sub-pixel included in the pixel PX may be a light emitting diode LED or an inorganic light emitting element (e.g., a micro-LED).

The micro-LED is an LED with a size of 10 to 100 μm and may be formed by growing a plurality of thin films made of an inorganic material, such as Al, Ga, N, P, As, or In, on a sapphire substrate or a silicon substrate and then cutting and separating the sapphire substrate or the silicon substrate. Since the micro-LEDs are formed in minute sizes, the micro-LEDs may be transferred to a flexible substrate such as plastic, making it possible to manufacture flexible display devices. Unlike an organic light emitting layer, since the micro-LEDs are formed by growing thin films made of an inorganic material, the manufacturing process is simplified, and a yield is increased. By simply transferring individually separated micro-LEDs on a large-area substrate, it is possible to manufacture a large-area display device. The micro-LED made of the inorganic material has advantages of high brightness, long lifetime, and low unit cost compared to the LED made of the organic light emitting material.

Although various types of lines for thin film transistors disposed on the substrate are formed by a photolithography process, the panel PN in which the sub-pixels are gathered may be manufactured through a different process. A micro-LED large-screen tiling display device TD may be manufactured by transferring the panel PN manufactured in units of blocks by a separate process to the substrate.

A method of manufacturing the micro-LED large-screen tiling display device TD may include forming a thin film transistor (TFT) and various lines on the substrate, transferring the micro-LED display panel PN manufactured in units of blocks on the substrate on which the TFT and the various lines are formed, tiling the plurality of micro-LED display panels PN, and the like.

In an embodiment, when the panels PN are tiled while being transferred in units of blocks BL, the distance D2 between the pixels PX which are present inside the same display panel PN and the distance D1 between neighboring pixels PX in different coupled display panels PN can be defined. Since the distance D2 between the pixels PX included in the same display panel PN in the X and/or Y directions is substantially the same, little error may occur.

As the panel PN is coupled to another panel, the distance D1 between the pixels included in different panels PN can be defined. Although efforts may be made toward that D1 be substantially the same as D2 so that a boundary between the panels PN or the blocks BL is not visible, errors due to a mechanical process in the transferring may occur. In this case, D1 may have a value smaller than or larger than D2.

In an embodiment, the micro-LEDs included in different blocks may not have the same luminous characteristics. In some embodiment, the luminous characteristics of the micro-LEDs included in different blocks be substantially the same. However, for example, since wavelengths of the micro-LEDs with peak luminous intensity in the manufacturing of the display panel in units of blocks BL are different in nm scale, the luminous characteristics of the micro-LED may be different.

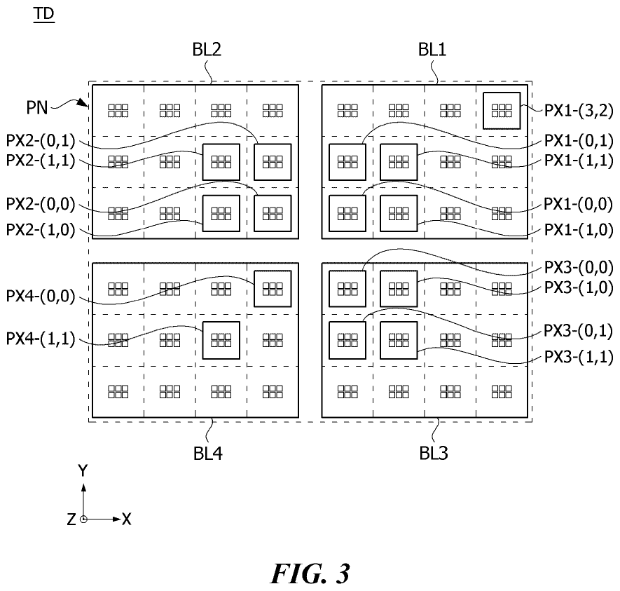

Referring to FIG. 3, the tiling display device TD according to some embodiments may include four display panels PN. Each display panel PN may be manufactured in units of blocks BL and tiled.

In an embodiment, the tiling display device TD may have four display panels PN coupled in a first direction (e.g., a longitudinal (X) direction) and/or a second direction intersecting the first direction (e.g., a width (Y) direction). The first direction can be construed as a line direction (or a row direction), and the second direction can be construed as a column direction (or a column direction).

The tiling display device TD according to some embodiments may include a plurality of pixel blocks BL2 and BL3 disposed in the X and Y directions with respect to one pixel block BL1.

As an example, FIG. 3 shows that a first pixel block BL1, a second pixel block BL2 disposed in the X direction with respect to the first pixel block BL1, a third pixel block BL3 disposed in the Y direction with respect to the first pixel block BL1, and a fourth pixel block BL4 disposed on a portion on which a virtual line extending in the Y direction with respect to the second pixel block BL2 and a virtual line extending in the X direction with respect to the third pixel block BL3 intersect. However, the present disclosure is not limited thereto, and as described above, pixel blocks may be included in the present disclosure as long as pixel blocks disposed in the first direction (e.g., the X direction) and the second direction (e.g., the Y direction) intersecting the first direction with respect to one pixel block can be defined.

The first pixel block BL1 may include a plurality of pixels PX disposed in the X and Y directions. FIG. 3 shows the first pixel block BL1 expressed by 4 lines in the X direction and 3 lines in the Y direction so that one pixel block BL1 includes 12 pixels PX. However, the present disclosure is not limited thereto, and since pixels with m lines (m is 1 or more) in the X direction and n lines (n is 1 or more) in the Y direction are present, one pixel block BL may include m×n pixels PX. A size of the pixel block BL is not limited to a specific size and may be set based on the result of image quality evaluation experiment.

Each pixel block BL may include a pixel (hereinafter referred to as “most neighboring pixel”) most neighboring to the pixel blocks which are present in the X direction and the pixel blocks which are present in the Y direction.

“Neighboring” indicates the relationship between the pixel and the pixel block or between the pixels in which another pixel is not present in the X direction in two different pixel blocks or the same pixel block, which are disposed in the X direction. Alternatively or additionally, “neighboring” also indicates the relationship between the pixel and the pixel block or between the pixels in which another pixel is not present in the Y direction in two different pixel blocks or the same pixel block, which are disposed in the Y direction.

For example, the first pixel block BL1 may include a pixel PX1-(0,0) most neighboring to both the pixel block BL2 which is present in the X direction and the pixel block BL3 which is present in the Y direction.

The second pixel block BL2 may include a pixel PX2-(0,0) most neighboring to both the pixel block BL1 which is present in the X direction and the pixel block BL4 which is present in the Y direction.

The third pixel block BL3 may include a pixel PX3-(0,0) most neighboring to both the pixel block BL4 which is present in the X direction and the pixel block BL1 which is present in the Y direction.

The fourth pixel block BL4 may include a pixel PX4-(0,0) most neighboring to both the pixel block BL3 which is present in the X direction and the pixel block BL2 which is present in the Y direction.

However, it is a relative concept, and pixels most neighboring to all the pixel blocks may vary depending on specific positions of the pixel blocks which are present in the X direction and the pixel blocks which are present in the Y direction.

For example, two pixel blocks which are present in the X direction of the first pixel block BL1 are provided, and the pixel block disposed in a +X direction rather than the pixel block (second pixel block BL2) disposed in a-X direction with respect to the first pixel block BL1 may be present. Likewise, two pixel blocks which are present in the Y direction of the first pixel block BL1 are provided, and the pixel block disposed in a +Y direction rather than the pixel block (third pixel block BL3) disposed in a −Y direction with respect to the first pixel block BL1 may be present. When the first pixel block includes pixels disposed in 3×4 as shown in FIG. 3, the most neighboring pixel to the pixel blocks is PX1-(3,2).

Each of the pixels included in the pixel block is indicated in a form of PXa-(b,c). a denotes a pixel block, b denotes the reference number of pixels in the X direction with respect to the most neighboring pixel in the same pixel block, and c denotes the reference number of pixels in the Y direction with respect to the most neighboring pixel in the same pixel block.

For example, the most neighboring pixel in the first pixel block is indicated by PX1-(0,0). In the first pixel block, a pixel positioned at a position which is spaced 3 pixels in the X direction and spaced 2 pixels in the Y direction from PX1-(0,0) is indicated by PX1-(3,2).

The most neighboring pixel in the second pixel block is indicated by PX2-(0,0). In the second pixel block, a pixel positioned at a position which is spaced 0 pixels in the X direction and spaced 1 pixel in the Y direction from PX2-(0,0) is indicated by PX2-(0,1).

The most neighboring pixel in the third pixel block is indicated by PX3-(0,0). In the third pixel block, a pixel positioned at a position which are spaced 1 pixel in the X direction and spaced 0 pixels in the Y direction from PX3-(0,0) is indicated by PX3-(1,0).

The most neighboring pixel in the fourth pixel block is indicated by PX4-(0,0). In the fourth pixel block, a pixel positioned at a position which is spaced 1 pixel in the X direction and spaced 1 pixel in the Y direction from PX4-(0,0) is indicated by PX4-(1,1).

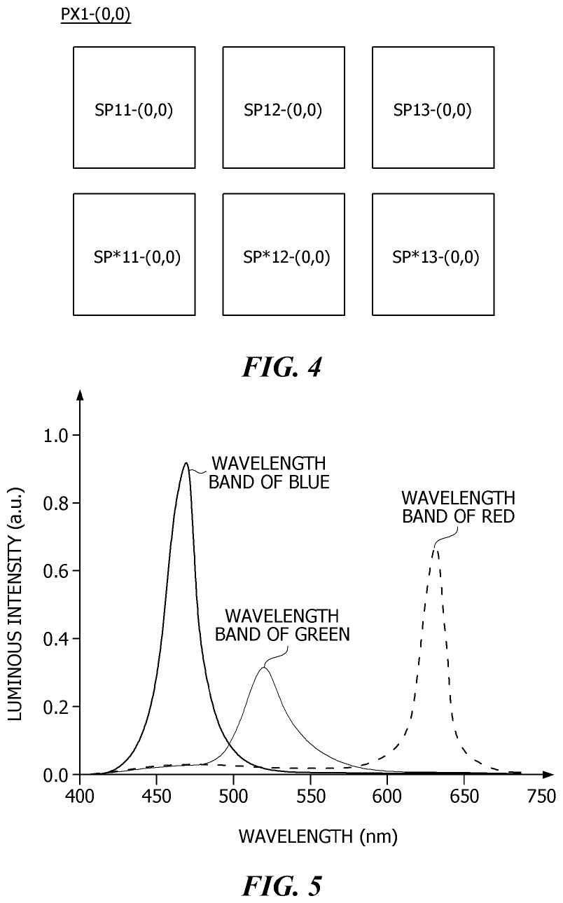

Referring to FIG. 4, in an embodiment, one pixel PX may include 6 sub-pixels SP. Each of the six sub-pixels may be a main light emitting element and an auxiliary light emitting element for a first color, a main light emitting element and an auxiliary light emitting element for a second color, and a main light emitting element and an auxiliary light emitting element for a third color.

The first to third colors may be any one selected from the group consisting of blue, green, and red and may not overlap each other. For example, the first color, the second color, and the third color may be red, blue, and green, respectively or may be blue, red, and green, respectively, but is not limited thereto.

Each sub-pixel included in the pixel is indicated in a form of SPad-(b,c) or SP*ad-(b,c).

SP and SP* each are any one selected from the group consisting of the main light emitting element and the auxiliary light emitting element in the same color and do not overlap each other.

In SPad-(b,c) or SP*ad-(b,c), the “*” does not specify any one of the main light emitting element and the auxiliary light emitting element and is indicated to distinguish the main light emitting element and the auxiliary light emitting element from each other. For descriptive purposes only, “a” denotes a pixel block, “d” denotes a color expressed by the sub-pixel, “b” denotes the reference number of pixels in the X direction with respect to the most neighboring pixel in the pixel block including pixels including the sub-pixels, and “c” denotes the reference number of pixels in the Y direction with respect to the most neighboring pixel in the pixel block including pixels including the sub-pixels.

For example, referring to FIGS. 3 and 4, FIG. 4 shows sub-pixels included in the pixel PX1-(0,0) most neighboring to the first pixel block BL1.

The main light emitting element and the auxiliary light emitting element for the first color are SP11-(0,0) and SP*11-(0,0) or SP*11-(0,0) and SP11-(0,0), respectively, the main light emitting element and the auxiliary light emitting element for the second color are SP12-(0,0) and SP*12-(0,0) or SP*12-(0,0) and SP12-(0,0), respectively, and the main light emitting element and the auxiliary light emitting element for the third color are SP13-(0,0) and SP*13-(0,0) or SP*13-(0,0) and SP13-(0,0), respectively.

Sub-pixels for different colors may have different luminous characteristics. The luminous characteristics of the sub-pixel may indicate a wavelength band of the color indicated by the sub-pixel.

Referring to FIG. 5, blue, green, and red may have different wavelength bands and show different luminous characteristics. For example, blue may have a wavelength band of 450 nm to 495 nm, green may have a wavelength band of 495 nm to 570 nm, and red may have a wavelength band of 620 nm to 750 nm. However, the present disclosure is not specific, and there may be a difference between upper and lower limits of the wavelength band for the same color depending on an operator.

In FIG. 5, an X-axis indicates a range (about 380 nm to 750 nm) of a wavelength band of a color sensed by cone cells of human, and a Y-axis indicates a relative value (arbitrary unit (a.u.)) of a luminous intensity.

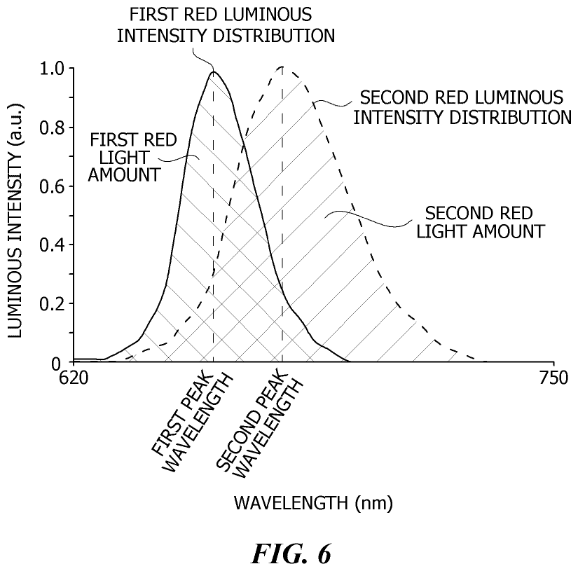

In FIGS. 6 to 8 below, units of the X-axis and the Y-axis except for some differences in the numerical range of the X-axis are the same as those in FIG. 5.

Sub-pixels for the same color may have different luminous characteristics. The luminous characteristics of the sub-pixel may indicate luminous intensity distribution according to the wavelength band of the color expressed by the sub-pixel. A photometry method well known in the art for analyzing luminous intensity distribution can be used, and for example, absorptiometry analysis using Lambert-Beer's law can be used.

In the luminous intensity distribution, luminous intensity represents the intensity of light coming from a light source in a specific direction, and may be expressed as luminous intensity. The luminous intensity distribution indicates the distribution of the luminous intensity according to the wavelength band of light for a specific color.

Even sub-pixels expressing the same color may have different luminous characteristics. When the luminous intensity distributions are different, peak wavelengths may be the same or different. The peak wavelength may indicate the wavelength with the highest luminous intensity in the wavelength band of a graph showing the luminous intensity distribution of a sub-pixel expressing a specific color which is any one of the first to third colors.

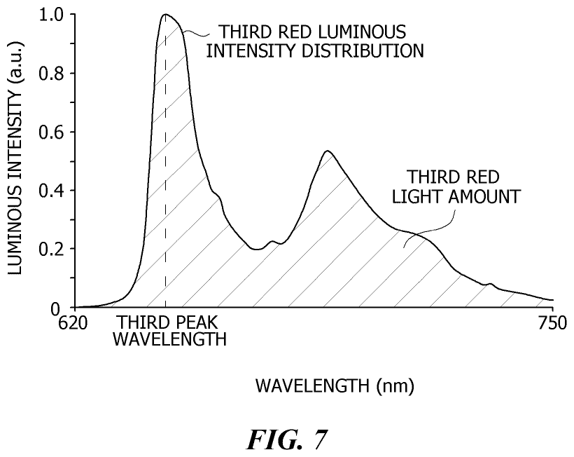

FIGS. 6 and 7 show shapes of luminous intensity distribution graphs according to wavelength bands of the red light emitting element.

The X-axis indicates a wavelength in the range of about 620 nm to 750 nm, first red luminous intensity distribution may have a first peak wavelength, second red luminous intensity distribution may have a second peak wavelength, and third red luminous intensity distribution may have a third peak wavelength.

The sub-pixels SP11-(0,0) and SP*11-(0,0) included in one pixel PX1-(0,0) and expressing the first color (e.g., red) may have first red luminous intensity distribution and second red luminous intensity distribution, respectively. SP11-(0,0) and SP*11-(0,0) may have the first peak wavelength and the second peak wavelength and have different luminous characteristics.

The light amount may indicate one color and indicate the total light amount emitted by the light emitting sub-pixel. The light amount may be proportional to a value obtained by integrating the luminous intensity distribution graph. In FIG. 6, since the Y-axis is the arbitrary unit (a.u.), the first red light amount may be proportional to the light amount of the light emitting element having the first red luminous intensity distribution.

Brightness may indicate one color and indicate the light amount reflected from a target surface in the light emitting sub-pixel. According to the standard of the target surface, the brightness may be proportional to the light amount.

When SP11-(0,0) and SP*11-(0,0) with different luminous characteristics each emit light, their light amounts and/or brightness may be the same. The light amount ratio of SP11-(0,0) and SP*11-(0,0) may be 1:1.

When one pixel PX1-(0,0) emits light of only the first color (e.g., one of red, green, and blue), only the sub-pixel SP11-(0,0) and SP*11-(0,0) included in the corresponding pixel and having different luminous characteristics may emit light. In a case in which both SP11-(0,0) and SP*11-(0,0) emit light, the luminous characteristics of SP11-(0,0), the luminous characteristics of SP*11-(0,0), and the luminous characteristics of PX1-(0,0) are different, the luminous characteristics of SP11-(0,0) and SP*11-(0,0) may be different. Furthermore, the luminous intensity distributions and peak wavelengths of these sub-pixels and PX1-(0,0) may be different.

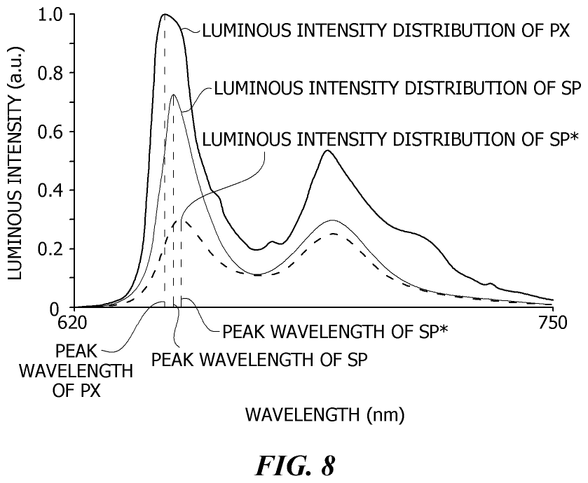

Referring to FIG. 8, in a case in which both the main light emitting element and the auxiliary light emitting element SP and SP* with different luminous intensity distributions emit light, the luminous intensity distribution of the pixel PX may be changed using the luminous intensity distributions of SP and SP* as variables.

Although the sub-pixels SP and SP* included in the pixel PX may not match exactly due to other variables such as constructive interference caused therebetween while emitting light, a luminous intensity of the pixel PX at a specific wavelength may be substantially the same as the sum of the luminous intensity of SP and the luminous intensity of SP* at the wavelength.

In addition, since the luminous intensity distributions of SP, SP*, and PX are different, their respective peak wavelengths may be different. Regarding the above-described light amount, unless other variables such as constructive interference caused by the sub-pixels SP and SP* included in the pixel PX while emitting light are considered, the light amount of PX may be substantially the same as the sum of the light amount of SP and the light amount of SP *.

The first pixel PX1-(0,0), which emits light of only the first color (one of red, green, and blue), may include the sub-pixels SP11-(0,0) and SP*11-(0,0) for the first color with different luminous intensity distributions. The second pixel PX2-(0,0), which emits light of only the first color, may include the sub-pixels SP21-(0,0) and SP*21-(0,0) for the first color with different luminous intensity distributions.

The luminous characteristics and/or luminous intensity distributions of the first pixel PX1-(0,0) and the second pixel PX2-(0,0), which emit light of only the first color (one of red, green, and blue), may be different.

As described above, the amounts of light and/or brightness of SP11-(0,0) and SP*11-(0,0) with different luminous characteristics may be the same. In this case, the light amount ratio of SP11-(0,0) and SP*11-(0,0) may be 1:1.

Similarly, when PX1-(0,0) and PX2-(0,0) with different luminous characteristics each emit light of the same color, their light amounts and/or brightness may be the same.

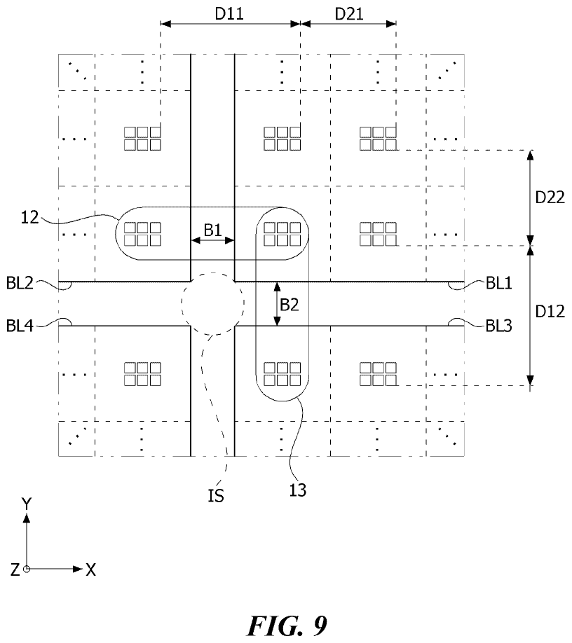

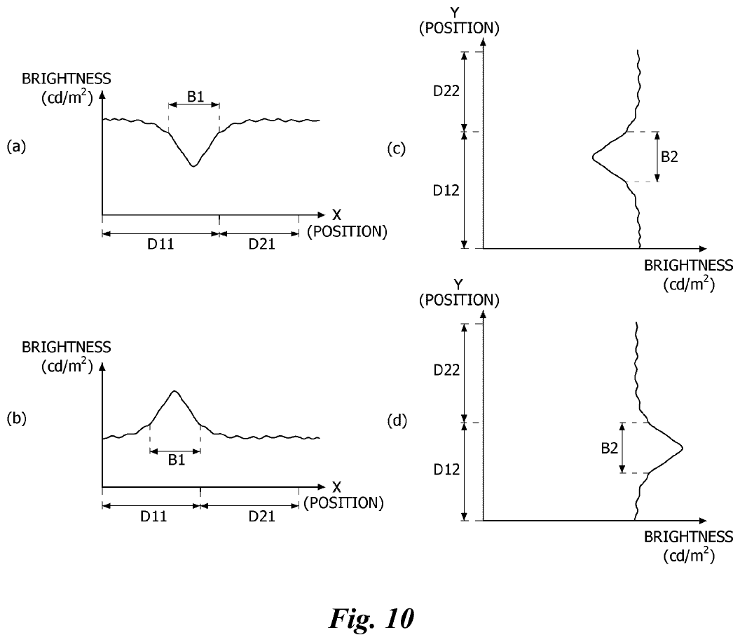

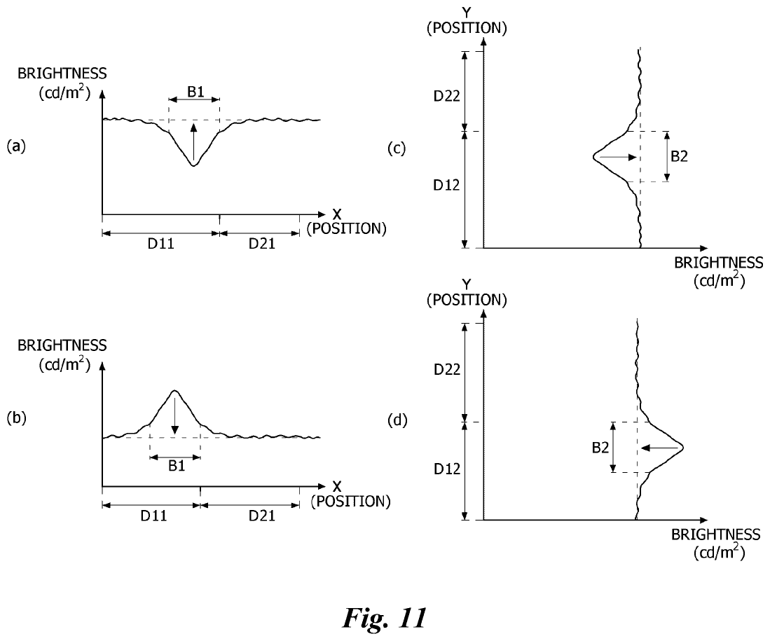

Referring to FIGS. 9 to 11, the tiling display device TD according to some embodiments may include a screen in which the first pixel block BL1 and the second pixel block BL2 are coupled on the same XY plane. However, the present disclosure is not limited thereto, and the screen may indicate a component in which at least three of the blocks BL1, BL2, BL3, and BL4 are coupled on the same plane.

The screen may include a plurality of pixel blocks BL1, BL2, BL3, and BL4, and each pixel block may include a plurality of pixels PX.

A direction in which the plurality of pixel blocks are arranged has already been described with reference to FIG. 3.

The first pixel block BL1 may include the pixel PX1-(0,0) most neighboring to both the second pixel block BL2 and the third pixel block BL3. PX1-(0,0) may include at least two sub-pixels SP11-(0,0) and SP*11-(0,0) which emit light in the wavelength band of the first color.

The second pixel block BL2 may include the pixel PX2-(0,0) most neighboring to both the first pixel block BL1 and the fourth pixel block BL4. PX2-(0,0) may be disposed to be spaced apart from PX1-(0,0) in the X direction. PX2-(0,0) may include at least two sub-pixels SP21-(0,0) and SP*21-(0,0) which emit light in the wavelength band of the first color.

The third pixel block BL3 may include the pixel PX3-(0,0) most neighboring to both the first pixel block BL1 and the fourth pixel block BL4. PX3-(0,0) may be disposed to be spaced apart from PX1-(0,0) in the Y direction and from PX4-(0,0) in the X direction. PX3-(0,0) may include at least two sub-pixels SP31-(0,0) and SP*31-(0,0) which emit light in the wavelength band of the first color.

Based on the above-described notation, all the sub-pixels referred to in the description herein may emit light in the wavelength band for the same first color for descriptive purposes. The same descriptions also apply to sub-pixels that emit light in the wavelength for a different color, as should be appreciated.

In an embodiment, the tiling display device TD may include a first area 12 including PX1-(0,0) and PX2-(0,0) and a second area 13 including PX1-(0,0) and PX3-(0,0). The tiling display device TD may include a distance B1 between boundaries of different pixel blocks BL1 and BL2 disposed in the X direction. The tiling display device TD may include a distance B2 between boundaries of different pixel blocks BL1 and BL3 disposed in the Y direction.

A distance D11 between the pixels PX1-(0,0) and PX2-(0,0) included in different pixel blocks BL1 and BL2 disposed in the X direction may be relatively larger than or smaller than a distance D21 between the pixels PX1-(0,0) and PX1-(1,0) included in the same pixel block BL1.

When D11 is relatively larger than D21, as shown in (a) of FIG. 10, brightness deviation between the first area 12 and an area including the pixels (e.g., PX1-(0,0) and PX1-(1,0)) with relative smaller distances may occur, and thus dark spots may be visible.

When D11 is relatively smaller than D21, as shown in (b) of FIG. 10, brightness deviation between the first area 12 and an area including the pixels (e.g., PX1-(0,0) and PX1-(1,0)) with a relative larger distance may occur, and thus bright spots may be visible.

A distance D12 between the pixels PX1-(0,0) and PX3-(0,0) included in different pixel blocks BL1 and BL3 disposed in the Y direction may be relatively larger than or smaller than a distance D22 between the pixels PX1-(0,0) and PX1-(0,1) included in the same pixel block BL1.

When D12 is relatively larger than D22, as shown in (c) of FIG. 10, brightness deviation between the second area 13 and an area including the pixels (e.g., PX1-(0,0) and PX1-(0,1)) with relative smaller distances may occur, and thus dark spots may be visible.

When D12 is relatively smaller than D22, as shown in (d) of FIG. 10, brightness deviation between the second area 13 and an area including the pixels (e.g., PX1-(0,0) and PX1-(0,1)) with a relative larger distance may occur, and thus bright spots may be visible.

As described above, the amounts of light and/or brightness of SP11-(0,0) and SP*11-(0,0) with different luminous characteristics may be the same. In this case, the light amount ratio of SP11-(0,0) and SP*11-(0,0) may be 1:1. When PX1-(0,0) and PX2-(0,0) with different luminous characteristics emit light of the same color (e.g., any one of red, green, and blue), their light amounts and/or brightness may be the same.

Similarly, when the first area 12 and the second area 13 emit light of the same color, their light amount and/or brightness are the same, and the luminous characteristics of the first area 12 and the second area 13 may be different.

When D11 is larger than D21, pixels with a relatively larger distance between neighboring pixels may be PX1-(0,0) and PX2-(0,0). In this case, pixels with a relatively smaller distance may be PX1-(0,0) and PX1-(1,0). When D12 is greater than D22, pixels with a relatively greater distance between neighboring pixels may be PX1-(0,0) and PX3-(0,0). In this case, pixels with a relatively smaller distance may be PX1-(0,0) and PX1-(0,1).

When D11 is smaller than D21, pixels with a relatively smaller distance between neighboring pixels may be PX1-(0,0) and PX2-(0,0). In this case, pixels with a relatively larger distance may be PX1-(0,0) and PX1-(1,0). When D12 is smaller than D22, pixels with a relatively smaller distance between neighboring pixels may be PX1-(0,0) and PX3-(0,0). In this case, pixels with a relatively greater distance may be PX1-(0,0) and PX1-(0,1).

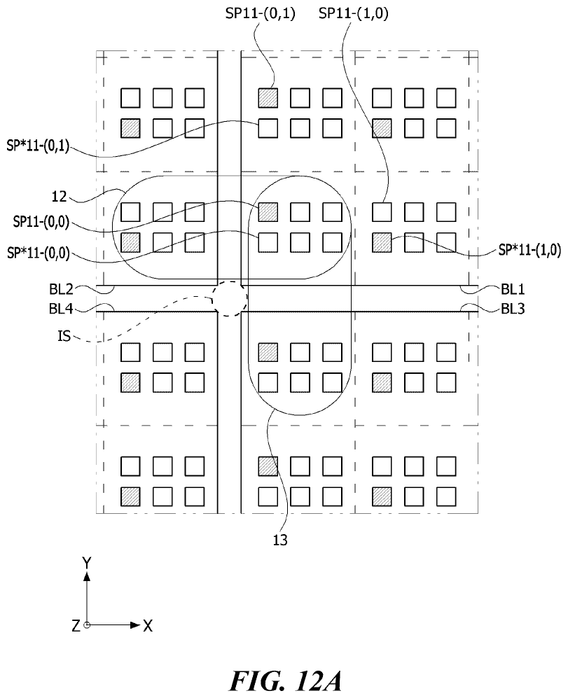

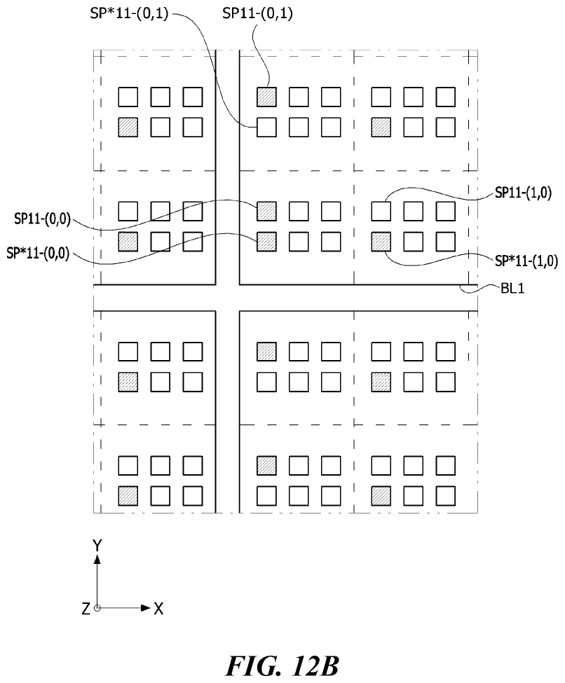

Referring to FIG. 12A, in a condition in which the brightness of the first color of the first area 12 and the brightness of the first color of the second area 13 are the same, when the distance between the neighboring pixels is relatively large (e.g., D11>D21 and D12>D22), the sum of brightness of the sub-pixels (e.g., SP11-(0,0) and SP*11-(0,0)) included in “any one (e.g., PX1-(0,0)) of the pixels PX1-(0,0) and PX2-(0,0) disposed in the X direction” and “any one (e.g., PX1-(0,0)) of the pixels PX1-(0,0) and PX3-(0,0) disposed in the Y direction” may be larger than the sum of brightness of the sub-pixels (e.g., SP11-(1,0) and SP*11-(1,0), and SP11-(0,1) and SP*11-(0,1)) included in the pixels (e.g., PX1-(1,0) and PX1-(0,1)) with a relatively smaller distance between the neighboring pixels.

Therefore, it is possible to compensate for the dark spots due to the distance deviation between the pixels, which may occur in a process of transferring the panels in units of block. In addition, by increasing the overall brightness of the pixels included in the areas 12 and 13 where there is relatively the distance deviation, it is possible to compensate for the dark spots which occur in the X and Y directions intersecting each other and the dark spots which may occur at the intersection IS (see FIGS. 11A and 11C). According to some embodiments, it is possible to improve image quality and visibility of the tiling display device.

Referring to FIG. 12B, in an embodiment, the light amount ratio of the sub-pixels (e.g., SP11-(0,0) and SP*11-(0,0)) of one (e.g., PX1-(0,0)) of the pixels PX1-(0,0) and PX2-(0,0) with a relatively larger distance between the neighboring pixels may differ from the light amount ratio of the sub-pixels (e.g., SP11-(1,0) and SP*11-(1,0)) of one (e.g., PX1-(1,0)) of the pixels PX1-(1,0) and PX1-(2,0) with a relatively smaller distance between the neighboring pixels.

In an embodiment, only any one of the sub-pixels SP11-(1,0) and SP*11-(1,0) of one of the pixels with a relatively smaller distance between the neighboring pixels may emit light. SP11-(1,0) may be in a state of being turned off, and SP*11-(1,0) may be in a state of being turned on. The light amount ratio of the sub-pixels SP11-(1,0) and SP*11-(1,0) may be 1:0 or 0:1.

Since the light amount ratio of the sub-pixels SP11-(0,0) and SP*11-(0,0) of one of the pixels with a relatively larger distance between the neighboring pixels differs from the above light amount ratio, both the sub-pixels SP11-(0,0) and SP*11-(0,0) may emit light under the first condition.

In some embodiments, to compensate for the dark spots, the light amount of another sub-pixel (e.g., SP*11-(0,0)) in the same pixel for the same color is increased additionally without additionally increasing the brightness of the previously light emitting sub-pixel (e.g., SP11-(0,0)) while maintaining the light amount ratio. Therefore, it is possible to extend the lifetime of the sub-pixel and prevent performance degradation.

In some embodiments, although the light amount ratio of the sub-pixels included in the pixels disposed in the X direction is described, the light amount ratio of the sub-pixels SP11-(0,0) and SP*11-(0,0) included in PX1-(0,0) and the light amount ratio of the sub-pixels SP11-(0,1) and SP*11-(0,1) included in PX1-(0,1), which are the pixels disposed in the Y direction, may be different.

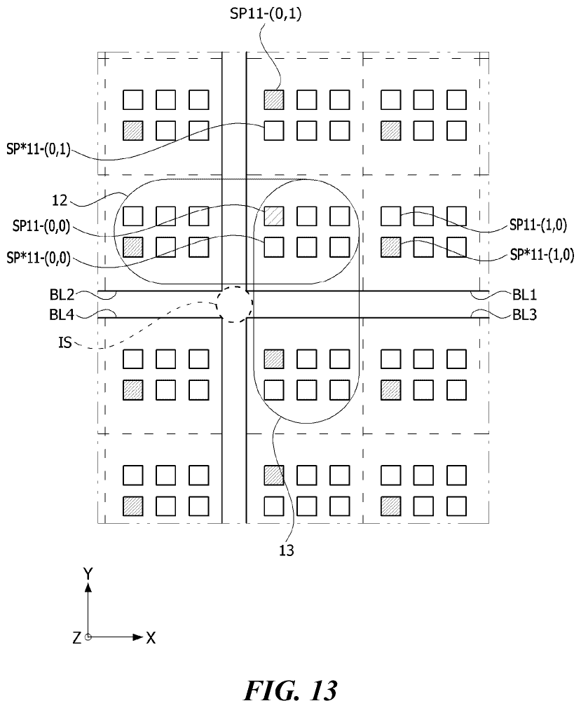

Referring to FIG. 13, in an embodiment, in a condition in which the brightness of the first color of the first area 12 and the brightness of the first color of the second area 13 are the same, when the distance between the neighboring pixels is relatively small (e.g., D11<D21 and D12<D22), the sum of brightness of the sub-pixels (e.g., SP11-(0,0) and SP*11-(0,0)) included in any one (e.g., PX1-(0,0)) of the pixels PX1-(0,0) and PX2-(0,0) disposed in the X direction and the pixels PX1-(0,0) and PX3-(0,0) disposed in the Y direction may be smaller than the sum of brightness of the sub-pixels (e.g., SP11-(1,0) and SP*11-(1,0)) included in the pixels (e.g., PX1-(1,0) and PX1-(0,1)) with a relatively larger distance between the neighboring pixels.

Therefore, in some embodiments, it is possible to compensate for the bright spots due to the distance deviation between the pixels, which may occur in the process of transferring the panels in units of block. In addition, by decreasing the overall brightness of the pixels included in the areas 12 and 13 where there is relatively the distance deviation, it is possible to compensate for the bright spots which occur in the X and Y directions intersecting each other and the bright spots which may occur at the intersection IS (see FIGS. 11B and 11D). According to some embodiments, it is possible to improve image quality and visibility of the tiling display device.

In an embodiment, the light amount ratio of the sub-pixels (e.g., SP11-(0,0) and SP*11-(0,0)) of one (e.g., PX1-(0,0)) of the pixels PX1-(0,0) and PX2-(0,0) with a relatively smaller distance between the neighboring pixels may be the same as the light amount ratio of the sub-pixels (e.g., SP11-(1,0) and SP*11-(1,0)) of one (e.g., PX1-(1,0)) of the pixels PX1-(1,0) and PX1-(2,0) with a relatively larger distance between the neighboring pixels.

In an embodiment, only any one of the sub-pixels SP11-(1,0) and SP*11-(1,0) of one of the pixels with a relatively larger distance between the neighboring pixels may emit light. SP11-(1,0) may be in a state of being turned off, and SP*11-(1,0) may be in a state of being turned on. SP11-(1,0) may be in a state of being turned on, and SP*11-(1,0) may be in a state of being turned off. The light amount ratio of the sub-pixels SP11-(1,0) and SP*11-(1,0) may be 1:0 or 0:1.

Since the light amount ratio of the sub-pixels SP11-(0,0) and SP*11-(0,0) of one of the pixels with a relatively smaller distance between the neighboring pixels is the same as the above light amount ratio, only any one of the sub-pixels SP11-(0,0) and SP*11-(0,0) may emit light.

In some embodiments, to compensate for the bright spots, it is not necessary to additionally drive another sub-pixel (e.g., SP*11-(0,0)) in the same pixel for the same color by additionally decreasing only the brightness of the previously light emitting sub-pixel (e.g., SP11-(0,0)) while maintaining the light amount ratio.

The light amount ratio of the sub-pixels SP11-(0,0) and SP*11-(0,0) of one of the pixels with a relatively smaller distance between the neighboring pixels may be the same as the light amount ratio of the sub-pixels SP11-(1,0) and SP*11-(1,0) of one of the pixels with a relatively larger distance between the neighboring pixels, and the sum of brightness of the sub-pixels included in each of the pixel may be different. Specifically, the sum of brightness of the sub-pixels SP11-(0,0) and SP*11-(0,0) of one of the pixels with a relatively smaller distance between the neighboring pixels may be smaller.

According to some embodiments, it is possible to reduce a driving current of the light emitting sub-pixel and reduce power consumption of the tiling display device.

In some embodiments, although the light amount ratio of the sub-pixels included in the pixels disposed in the X direction is described (see FIG. 13A), the light amount ratio of the sub-pixels SP11-(0,0) and SP*11-(0,0) included in PX1-(0,0) and the light amount ratio of the sub-pixels SP11-(0,1) and SP*11-(0,1) included in PX1-(0,1), which are the pixels disposed in the Y direction, may be the same. Specifically, the light amount ratios may be the same, and the sum of brightness of the sub-pixels included in each of the pixels may be different. More specifically, the sum of brightness of the sub-pixels SP11-(0,0) and SP*11-(0,0) may be relatively smaller.

In some embodiments, the distance between the neighboring pixels may correspond to all the pixels with a relatively larger and/or relative smaller distance between the neighboring pixels. For example, when the distance between the pixels (e.g., PX1-(0,0) and PX2-(0,0)) disposed in the X direction is relatively larger and the distance between the pixels (e.g., PX1-(0,0) and PX3-(0,0)) disposed in the Y direction is relatively larger, there may be deviation in each of the sums of brightness of the sub-pixels disposed in the pixels disposed in the X and Y directions.

Alternatively or additionally, for example, when the distance between the pixels (e.g., PX1-(0,0) and PX2-(0,0)) disposed in the X direction is relatively larger and the distance between the pixels (e.g., PX1-(0,0) and PX3-(0,0)) disposed in the Y direction is relatively smaller, there may be deviation in each of the sums of brightness of the sub-pixels disposed in the pixels disposed in the X and Y directions.

Alternatively or additionally, when the distance between the pixels (e.g., PX1-(0,0) and PX2-(0,0)) disposed in the X direction is relatively smaller and the distance between the pixels (e.g., PX1-(0,0) and PX3-(0,0)) disposed in the Y direction is relatively larger, there may be deviation in each of the sums of brightness of the sub-pixels disposed in each of the pixels disposed in the X and Y directions.

Alternatively or additionally, when the distance between the pixels (e.g., PX1-(0,0) and PX2-(0,0)) disposed in the X direction is relatively smaller and the distance between the pixels (e.g., PX1-(0,0) and PX3-(0,0)) disposed in the Y direction is relatively smaller, there may be deviation in each of the sums of brightness of the sub-pixels disposed in each of the pixels disposed in the X and Y directions.

Therefore, it is possible to compensate for both the dark spots which occur in the X and Y directions intersection each other and the dark spots which may occur at the intersection IS. Since the dark spots and the bright spots are compensated for in the first direction, the second direction, and a direction between the first direction and the second direction of the tiling display device, it is possible to improve image quality in the entire area including the boundary between the blocks of the display device and improve color reproducibility.

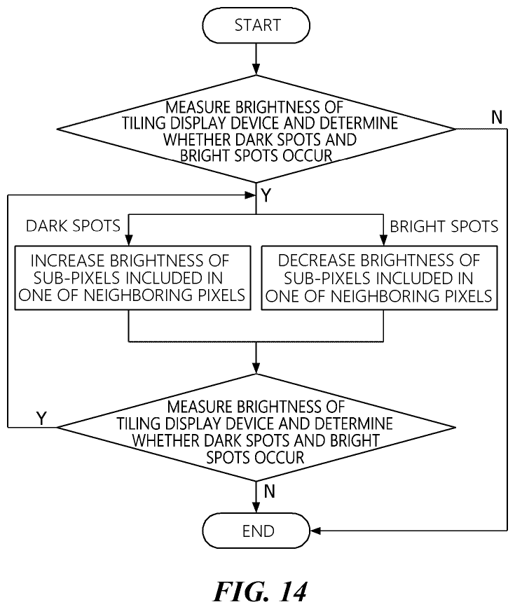

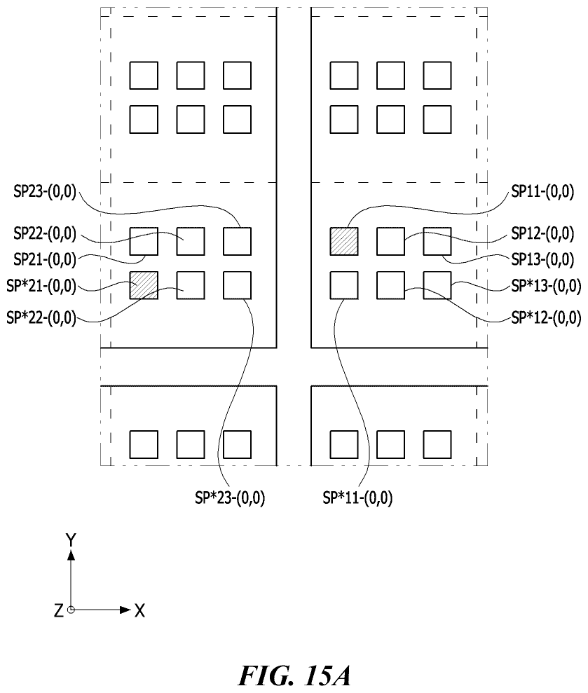

Referring to FIG. 14, a dark spot and bright spot compensation algorithm of the tiling display device measures the brightness of the tiling display device and determines whether dark spots or bright spots occur. When the dark spots or the bright spots do not occur, the algorithm is ended. In the case of being classified as the dark spots, the brightness of the sub-pixels included in one of the neighboring pixels is increased. In the case of being classified as the bright spots, the brightness of the sub-pixels included in one of the neighboring pixels is decreased. To determine whether the dark spots and the bright spots are still present, the brightness of the tiling display device with corrected brightness is re-measured. In case of non-occurrence, the algorithm is ended, and in case of occurrence, processing corresponding to the case of being classified into the dark spots or the bright spots is repeated.

As described above with reference to FIGS. 6 to 8, the sub-pixels with different luminous intensity distributions may have the same or different peak wavelengths, and the peak wavelength may indicate a wavelength with the highest luminous intensity in the luminous intensity distribution of the sub-pixel expressing a specific color. In this case, although the same color is expressed, there is deviation in saturation and/or brightness for the color due to different wavelengths even upon implementing the same color, and when the deviation is recognized by an observer, color reproducibility can be reduced.

The first pixel PX1-(0,0) may include at least two sub-pixels SP11-(0,0) and SP*11-(0,0) which emit light in the wavelength band of the first color (e.g., red). The second pixel PX2-(0,0) disposed to be spaced apart from the first pixel PX1-(0,0) in the X direction and neighboring to the first pixel may include at least two sub-pixels SP21-(0,0) and SP*21-(0,0) which emit light in the wavelength band of the red.

SP21-(0,0) may be disposed to be spaced apart from SP11-(0,0) in the X direction, and SP*21-(0,0) may be disposed to be spaced apart from SP*11-(0,0) in the X direction.

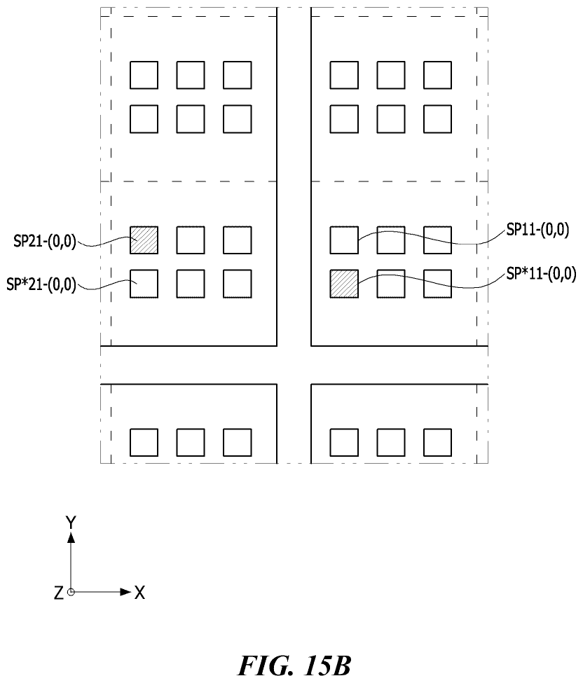

Referring to FIG. 15A, in a first pattern, under a condition in which the brightness of the first color of the first pixel PX1-(0,0) is the same as the brightness of the first color of the second pixel PX2-(0,0), SP11-(0,0) and SP*21-(0,0) may be in a state of being turned on, and SP*11-(0,0) and SP21-(0,0) may be in a state of being turned off. The first pattern may be a pattern in which the light amount ratio of SP11-(0,0) and SP*11-(0,0) is 1:0 and the light amount ratio of SP21-(0,0) and SP*21-(0,0) is 0:1 under the condition in which the brightness of the first color of the first pixel PX1-(0,0) is the same as the brightness of the first color of the second pixel PX2-(0,0). Referring to FIG. 15B, in a second pattern, under the condition in which the brightness of the first color of the first pixel PX1-(0,0) is the same as the brightness of the first color of the second pixel PX2-(0,0), SP11-(0,0) and SP*21-(0,0) may be in a state of being turned off, and SP*11-(0,0) and SP21-(0,0) may be in a state of being turned on. A second pattern may be a pattern in which the light amount ratio of SP11-(0,0) and SP*11-(0,0) is 0:1 and the light amount ratio of SP21-(0,0) and SP*21-(0,0) is 1:0 under the condition in which the brightness of the first color of the first pixel PX1-(0,0) is the same as the brightness of the first color of the second pixel PX2-(0,0).

Hereinafter, when a light amount ratio of a certain sub-pixel and another sub-pixel is 1:0, the sub-pixel of which the light amount ratio is I may be regarded as being in a state of being turned on, and the sub-pixel of which the light amount ratio is 0 may be regarded as being in a state of being turned off.

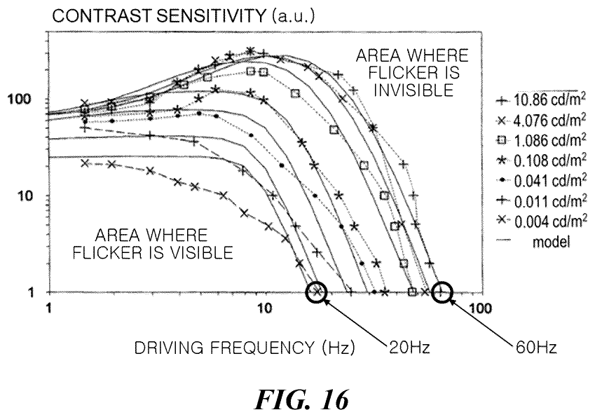

In the tiling display device according to some embodiments, the first pattern and the second pattern may be alternately driven in time. In an embodiment, different sub-pixels SP11-(0,0) and SP*11-(0,0) included in the same pixel (e.g., PX1-(0,0)) may be driven at different times. A different time driving condition is that flicker which appears when the sub-pixels expressing the same color are alternately driven in time is invisible. Detailed description thereof will be made with reference to FIG. 16.

Referring to FIG. 16, when any one of the first pattern and the second pattern appears in one frame, the flicker may be invisible when the sub-pixels are driven at 60 Hz or higher. When the brightness of the sub-pixel is low (e.g., 0.004 cd/m² or less), the flicker of the sub-pixel may be invisible when the sub-pixels are alternately driven at 20 Hz or higher.

By alternately driving the sub-pixels in time as described above, there is a possibility to reduce the deviation from a target peak wavelength in the tiling display device. Therefore, deviations in brightness or color/saturation which occur at the boundary of the tiling display device may be invisible, thereby improving color reproducibility and improving the image quality of the display device.

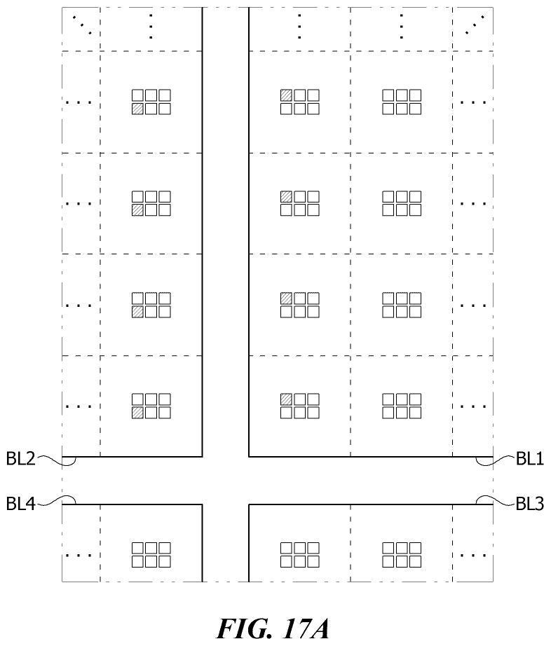

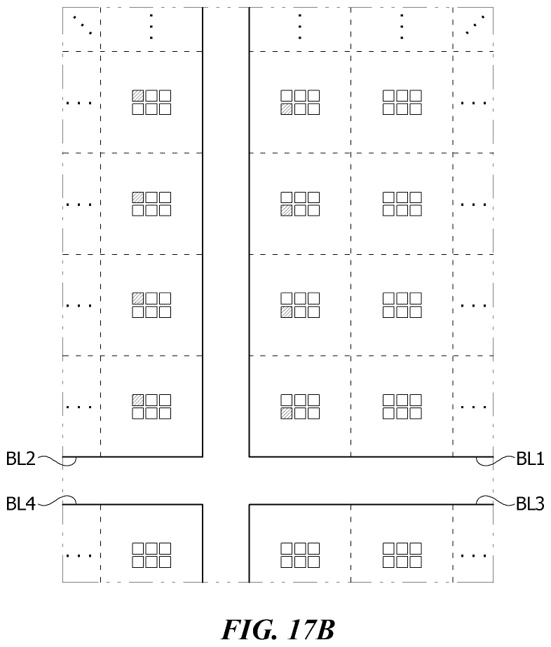

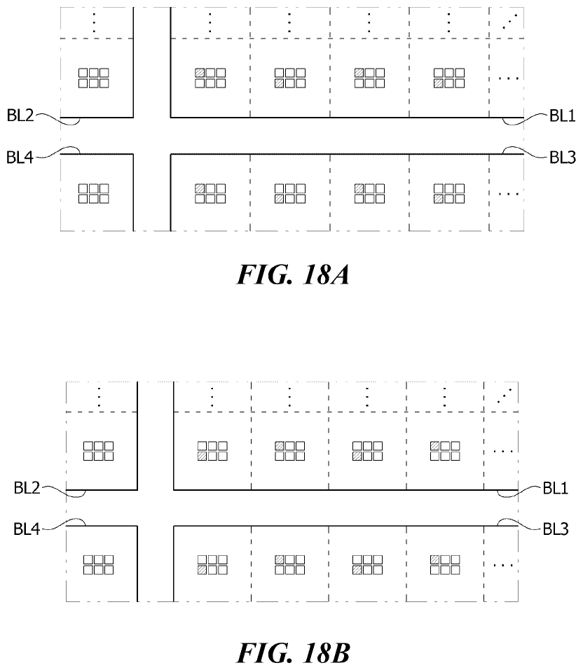

FIGS. 17A, 17B, 18A and 18B show exemplary driving patterns of the corresponding sub-pixels in some embodiments. Upon compared to FIG. 16, the number of pixels shown is different.

Referring to FIG. 17A and 17B, in an embodiment, the first pattern may be a pattern in which the light amount ratio of SP11-(0,0) and SP*11-(0,0), the light amount ratio of SP11-(0,1) and SP*11-(0,1), the light amount ratio of SP11-(0,2) and SP*11-(0,2), and the light amount ratio of SP11-(0,3) and SP*11-(0,3) are 1:0, and the light amount ratio of SP21-(0,0) to SP*21-(0,0), the light amount ratio of SP21-(0,1) and SP*21-(0,1), the light amount ratio of SP21-(0,2) and SP*21-(0,2), and the light amount ratio of SP21-(0,3) and SP*21-(0,3) are 0:1 (see FIG. 17A). The second pattern may be a pattern in which the light amount ratio of SP11-(0,0) and SP*11-(0,0), the light amount ratio of SP11-(0,1) and SP*11-(0,1), the light amount ratio of SP11-(0,2) and SP*11-(0,2), and the light amount ratio of SP11-(0,3) and SP*11-(0,3) are 0:1, and the light amount ratio of SP21-(0,0) and SP*21-(0,0), the light amount ratio of SP21-(0,1) and SP*21-(0,1), the light amount ratio of SP21-(0,2) and SP*21-(0,2), and the light amount ratio of SP21-(0,3) and SP*21-(0,3) are 1:0 (sec FIG. 17B).

Referring to FIG. 18A and 18B, in an embodiment, the first pattern may be a pattern in which the light amount ratio of SP11-(0,0) and SP*11-(0,0), the light amount ratio of SP11-(2,0) and SP*11-(2,0), the light amount ratio of SP31-(0,0) and SP*31-(0,0), and the light amount ratio of SP31-(2,0) and SP*31-(2,0) are 1:0, and the light amount ratio of SP11-(1,0) and SP*11-(1,0), the light amount ratio of SP11-(3,0) and SP*11-(3,0), the light amount ratio of SP31-(1,0) and SP*31-(1,0), and the light amount ratio of SP31-(3,0) and SP*31-(3,0) are 0:1 (see FIG. 18A). The second pattern may be a pattern in which the light amount ratio of SP11-(0,0) and SP*11-(0,0), the light amount ratio of SP11-(2,0) and SP*11-(2,0), the light amount ratio of SP31-(0,0) and SP*31-(0,0), and the light amount ratio of SP31-(2,0) and SP*31-(2,0) are 0:1, and the light amount ratio of SP11-(1,0) and SP*11-(1,0), the light amount ratio of SP11-(3,0) and SP*11-(3,0), the light amount ratio of SP31-(1,0) and SP*31-(1,0), and the light amount ratio of SP31-(3,0) and SP*31-(3,0) are 1:0 (see FIG. 18B).

According to some embodiments, since the first pattern and the second pattern may appear alternately in time, it is possible to prevent the degradation of the image quality due to the deviation of the peak wavelengths of the sub-pixels at the boundary between the first pixel block BL1 and the second pixel block BL2 and/or the boundary between the first pixel block BL1 and the third pixel block BL3. Therefore, it is possible to improve the visibility of the tiling display device.

In an embodiment, under a condition in which the brightness of the first color of PX1-(0,0) and the brightness of the first color of PX2-(0,0) are the same, the light amount ratio of SP11-(0,0) and SP*11-(0,0) may be in the range of 1:0.1 to 0.1:1, and the light amount ratio of SP21-(0,0) and SP*21-(0,0) may be in the range of 1:0 to 0:1. SP11-(0,0) and SP*11-(0,0) may be driven at the same time.

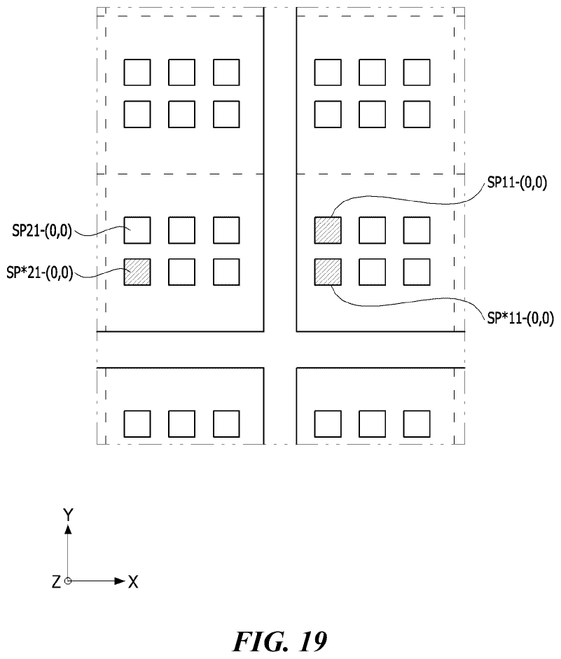

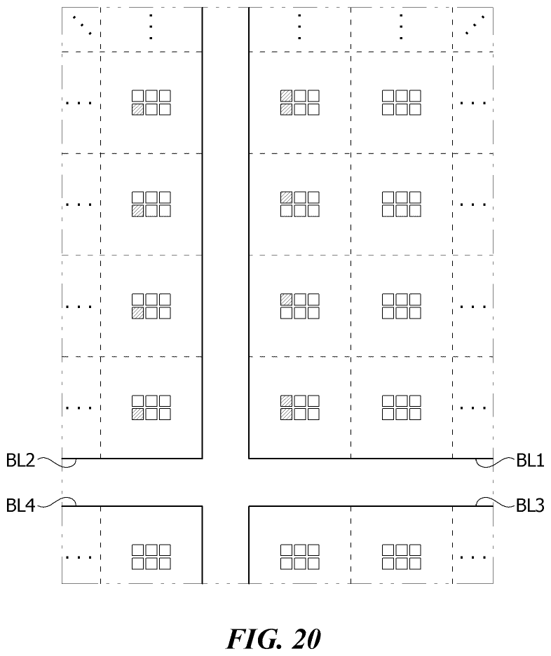

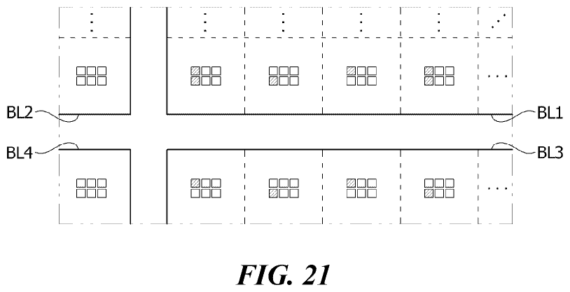

Referring to FIG. 19, when the light amount ratio of SP21-(0,0) and SP*21-(0,0) is 1:0 or 0:1, it may correspond to a case in which only any one (e.g., SP*21-(0,0)) of the sub-pixels emits light. When the light amount ratio of SP21-(0,0) and SP*21-(0,0) is 1:0 or 0:1, it may correspond to a state in which only any one (e.g., SP*21-(0,0)) of the sub-pixels is turned on.

When only any one (e.g., SP11-(0,0)) of the sub-pixels (e.g., SP11-(0,0) and SP*11-(0,0)) included in the same pixel (e.g., PX1-(0,0)) emits light to generate distribution of the wavelength, the image quality of the display device can be degraded.

At the time at which the sub-pixels are driven, the sub-pixel (e.g., SP*11-(0,0)) with a similar wavelength to that of the light emitting sub-pixel among SP21-(0,0) and SP*21-(0,0) may be driven additionally. The light amount ratio of the SP11-(0,0) and SP*11-(0,0) may be in the range of 1:0.1 to 0.1:1. Hereinafter, when a light amount ratio of a certain sub-pixel and another sub-pixel is 1:0.1, the sub-pixel of which the light amount ratio is 1 may be regarded as being in a state of being turned on, and the sub-pixel of which the light amount ratio is 0.1 may be regarded as being in a state of being turned on. It is possible to reduce the deviation of the peak wavelengths of SP11-(0,0) driven previously and SP*21-(0,0) by SP*11-(0,0) driven additionally. According to some embodiments, it is possible to prevent the degradation of the image quality due to the deviation of the wavelengths of the sub-pixels at the boundary. Therefore, it is possible to improve the visibility of the tiling display device and improve color reproducibility.

The relationship between the sub-pixels with “similar wavelengths” may mean that an absolute value of the difference between the peak wavelengths is 0 nm or more and 5 nm or less. By additionally driving the sub-pixels with similar wavelengths among the sub-pixels included in the neighboring pixels, it is possible to improve the mixing effect of the wavelengths. Therefore, it is possible to further improve the image quality of the display device.

The brightness of SP11-(0,0) and SP*11-(0,0) driven at the same time may be half the generally driven brightness.

“Generally driven brightness” of SP11-(0,0) may indicate the brightness of SP11-(0,0) which emits light when the corresponding display device is driven. “Generally driven brightness” of SP*11-(0,0) may indicate the brightness of light emitting SP*11-(0,0) when the corresponding display device is driven while SP*11-(0,0) emits light.

Since two or more sub-pixels expressing one specific color in one pixel PX1-(0,0) may emit light to rapidly increase brightness, according to some embodiments, SP*11-(0,0) may be driven additionally, and bright spots which may occur between PX1-(0,0) and PX2-(0,0) can be prevented.

FIGS. 20 and 21 show exemplary driving patterns of the corresponding sub-pixels in some embodiments. Upon compared to FIG. 19, the number of pixels shown is different.

FIG. 20 shows exemplary driving patterns of sub-pixels (e.g., SP11-(0,2) and SP21-(0,2) or SP*11-(0,2) and SP*21-(0,2)) (hereinafter, referred to as “corresponding sub-pixels”) disposed in the X direction among the sub-pixels expressing the first color included in the pixels (e.g., PX1-(0,2) and PX2-(0,2)) spaced the same distance from the most neighboring pixel (PX1-(0,0) and PX2-(0,0)), which is a reference point in each of the pixel blocks BL1 and BL2, in the Y direction.

Referring to FIG. 20, in the tiling display device according to some embodiments, when the peak wavelengths are similar like SP*11-(0,0) which is a sub-pixel corresponding to SP*21-(0,0), both SP11-(0,0) and SP*11-(0,0) are driven, and when the peak wavelengths are not similar like SP*11-(0,1) which is a sub-pixel corresponding to SP*21-(0,1), only any one of SP11-(0,0) and SP*11-(0,0) may be driven.

Some embodiments describes the sub-pixels included in the pixel blocks BL1 and BL2 disposed in the X direction, but as shown in FIG. 21, can also be applied to the pixel blocks BL1 and BL3 disposed in the Y direction.

As described above, the luminous characteristics and/or luminous intensity distributions of the first pixel PX1-(0,0) and the second pixel PX2-(0,0), which emit light of only the same color, may be different. When SP*11-(0,0) with the wavelength similar to that of SP*21-(0,0) is driven additionally, the luminous intensity distribution of PX1-(0,0) for the first color and the luminous intensity distribution of PX2-(0,0) for the first color may be different even when the brightness of both pixels is the same.

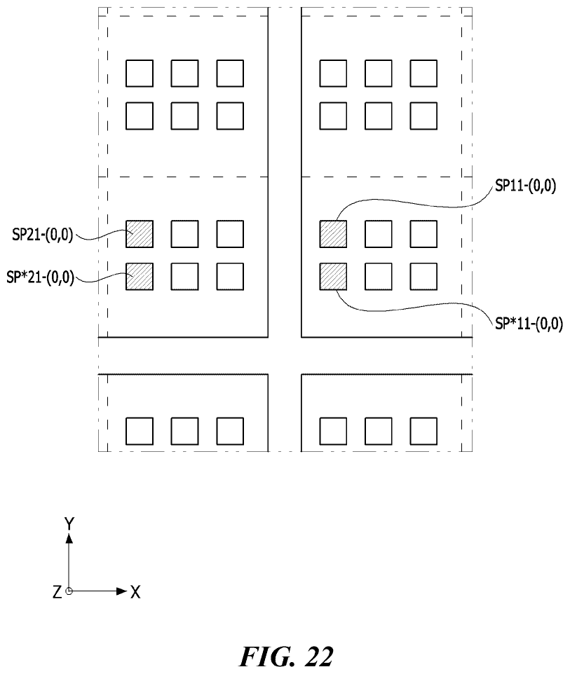

Referring to FIG. 22, in an embodiment, under a condition in which the brightness of the first color of PX1-(0,0) and the brightness of the first color of PX2-(0,0) are the same, the light amount ratio of SP11-(0,0) and SP*11-(0,0) may be in the range of 1:0.1 to 0.1:1, and the light amount ratio of SP21-(0,0) and SP*21-(0,0) may be in the range of 1:0.1 to 0.1:1. Specifically, both the sub-pixels SP21-(0,0) and SP*21-(0,0) of the first color of PX2-(0,0) may emit light.

When all the sub-pixels with different wavelengths are driven, there is a possibility to reduce the deviation due to the distribution of the peak wavelengths, and the image quality of the display device can be improved. In addition, it is possible to improve visibility and make color expression or reproducibility uniform.

In one embodiment, under the condition in which the brightness of the first color of PX1-(0,0) and the brightness of the first color of PX2-(0,0), which are neighboring, are the same, the light amount ratio of SP11-(0,0) and SP*11-(0,0) may be the same as the light amount ratio of SP21-(0,0) and SP*21-(0,0). Specifically, the light amount ratio of SP11-(0,0) and SP*11-(0,0) may be the same as the light amount ratio of SP21-(0,0) and SP*21-(0,0). Therefore, it is possible to easily and simply adjust the driving current at which the light amount of the display device is adjusted, thereby reducing the power consumption of the display device.

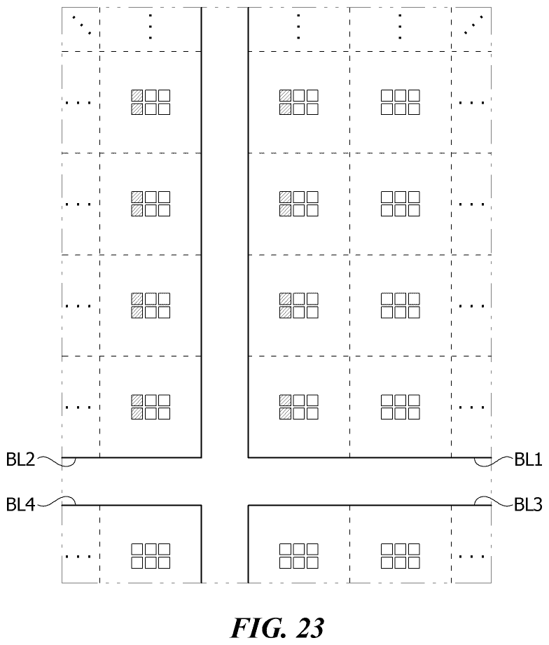

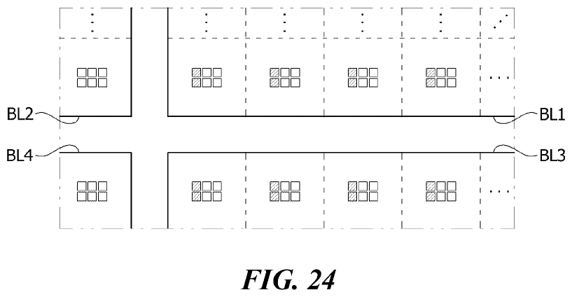

FIGS. 23 and 24 show exemplary driving patterns of the corresponding sub-pixels in some embodiments. Upon compared to FIG. 22, the number of pixels shown is different.

Referring to FIG. 23, in the tiling display device according to some embodiments, all the corresponding sub-pixels expressing the same color in the neighboring pixels included in different pixel blocks may be driven.

Some embodiments describes the sub-pixels included in the pixel blocks BL1 and BL2 disposed in the X direction, but as shown in FIG. 24, can also be applied to the pixel blocks BL1 and BL3 disposed in the Y direction.

According to embodiments, it is possible to compensate for dark spots and/or bright spots due to a distance deviation between pixels, which can occur in a process of transferring panels in units of blocks.

According to some embodiments, it is possible to compensate for dark spots and/or bright spots which can be generated at an intersection formed by coupling four or more pixel blocks.

According to some embodiments, it is possible to improve image quality and visibility of a tiling display device and prevent degradation of color reproducibility.

According to some embodiments, it is possible to reduce power consumption of the tiling display device.

Some of the embodiments are described using a pixel(s) that neighbors two other pixel blocks BL, which does not limit the scope of the disclosure. In some embodiments, the similar descriptions, e.g., the configuration of the brightness and/or the light amount ratio, may be used for the configuration of a pixel that neighbors only one other pixel block, e.g., a pixel in a pixel block that is arranged proximate to a border of the pixel block. That is, the variations in the configuration of the brightness and/or light amount ratio of a pixel can be used to compensate for the variations in distances between pixels caused by the tiling of display panels. Further, the similar configuration of the brightness and/or the light amount ratio of a pixel may also be used in a scenario that in a same pixel block, pixels are arranged with different distances between or among pixels or subpixels. For example, in a scenario that transmissive areas are arranged among pixels or subpixels.

The contents of the specification described in the above-described technical problem, technical solution, and advantageous effects are illustrative examples, and do not limit features of the claims, the scope of the claims is not limited by the items described in the contents of the specification.

Although embodiments of the present disclosure have been described in detail with reference to the accompanying drawings, the present disclosure is not necessarily limited to some embodiments, and various modifications may be carried out without departing from the technical spirit of the present disclosure. Therefore, some embodiments disclosed in the present disclosure are not intended to limit the technical spirit of the present disclosure, but for describing it, and the scope of the technical spirit of the present disclosure is not limited by some embodiments. It should be understood that the above-described embodiments are illustrative and not restrictive in all respects. The scope of the present disclosure should be construed according to the appended claims, and all technical spirits within the equivalent range should be construed as being included in the scope of the present disclosure.

The various embodiments described above can be combined to provide further embodiments. Aspects of some embodiments can be modified, if necessary to employ concepts of the various embodiments to provide yet further embodiments.

These and other changes can be made to some embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A tiling display device comprising:
a plurality of pixels disposed on a display panel;
a first pixel area including a first pixel and a second pixel neighboring to each other; and
a second pixel area including the first pixel and a third pixel neighboring to each other,
wherein in operation, a brightness of a first color of the first pixel area is same as a brightness of the first color of the second pixel area, and
a sum of brightness for each color of any one of two pixels selected from a group including the first pixel, the second pixel, and the third pixel is larger than a sum of brightness for each color of each of two pixels between which a distance is smaller than a distance between the two pixels selected from the group.

2. The tiling display device of claim 1, further comprising:
a first pixel block including the first pixel configured to emit light in a wavelength band of the first color;
a second pixel block including the second pixel spaced apart from the first pixel in a first direction and configured to emit light in the wavelength band of the first color; and
a third pixel block including the third pixel spaced apart from the first pixel in a second direction intersecting the first direction and configured to emit light in the wavelength band of the first color.

3. The tiling display device of claim 2, wherein a distance between the neighboring first and second pixels is larger than a distance between neighboring pixels in the first pixel block or in the second pixel block, and
a distance between the neighboring first and third pixels is larger than a distance between neighboring pixels in the first pixel block or in the third pixel block.

4. The tiling display device of claim 3, wherein the first pixel includes a 1-1 sub-pixel and a 1-2 sub-pixel configured to emit light in the wavelength band of the first color,
the second pixel includes a 2-1 sub-pixel and a 2-2 sub-pixel configured to emit light in the wavelength band of the first color,
the third pixel includes a 3-1 sub-pixel and a 3-2 sub-pixel configured to emit light in the wavelength band of the first color, and
the first color is one of red, green, or blue.

5. The tiling display device of claim 4, wherein a light amount ratio for the first color of the sub-pixels included in any one of the two pixels selected from the group differs from a light amount ratio for the first color of the sub-pixels included in the one of the two pixels between which the distance is smaller than the distance between the two selected pixels.

6. A tiling display device comprising:
a plurality of pixels disposed on a display panel;
a first pixel area including a first pixel and a second pixel neighboring to each other; and
a second pixel area including the first pixel and a third pixel neighboring to each other,
wherein a brightness of a first color of the first pixel area is same as a brightness of the first color of the second pixel area, and
a sum of brightness for each color of any one of two pixels selected from a group including the first pixel, the second pixel, and the third pixel is smaller than a sum of brightness for each color of each of two pixels between which a distance is larger than a distance between the two pixels selected from the group.

7. The tiling display device of claim 6, further comprising:
a first pixel block including the first pixel configured to emit light in a wavelength band of the first color;
a second pixel block including the second pixel spaced apart from the first pixel in a first direction and configured to emit light in the wavelength band of the first color; and
a third pixel block including the third pixel spaced apart from the first pixel in a second direction intersecting the first direction and configured to emit light in the wavelength band of the first color.

8. The tiling display device of claim 7, wherein a distance between the neighboring first and second pixels is smaller than a distance between neighboring pixels in the first pixel block or in the second pixel block, and
a distance between the neighboring first and third pixels is smaller than a distance between neighboring pixels in the first pixel block or in the third pixel block.

9. The tiling display device of claim 8, wherein the first pixel includes a 1-1 sub-pixel and a 1-2 sub-pixel configured to emit light in the wavelength band of the first color,
the second pixel includes a 2-1 sub-pixel and a 2-2 sub-pixel configured to emit light in the wavelength band of the first color,
the third pixel includes a 3-1 sub-pixel and a 3-2 sub-pixel configured to emit light in the wavelength band of the first color, and
the first color is one of red, green, or blue.

10. The tiling display device of claim 9, wherein a light amount ratio for the first color of the sub-pixels included in any one of the two pixels selected from the group is same as a light amount ratio for the first color of the sub-pixels included in the one of the two pixels between which the distance is larger than the distance between the two pixels selected from the group.

11. A tiling display device comprising:
a first pixel including a 1-1 sub-pixel and a 1-2 sub-pixel configured to emit light in a same wavelength band of a first color; and
a second pixel spaced apart from the first pixel and including a 2-1 sub-pixel and a 2-2 sub-pixel that configured to light in a same wavelength band of the first color,
wherein in operation, a first pattern, in which the 1-1 sub-pixel and the 2-2 sub-pixel are turned on and the 1-2 sub-pixel and the 2-1 sub-pixel are turned off, and a second pattern, in which the 1-1 sub-pixel and the 2-2 sub-pixel are turned off and the 1-2 sub-pixel and the 2-1 sub-pixel are turned on, appear alternately in time.

12. The tiling display device of claim 11, wherein, the 2-1 sub-pixel is spaced apart from the 1-1 sub-pixel in a first direction, and the 2-2 sub-pixel is spaced apart from the 1-2 sub-pixel in the first direction.

13. The tiling display device of claim 11, further comprising:
a first pixel block including the first pixel; and
a second pixel block including the second pixel spaced apart from the first pixel in a first direction and neighboring to the first pixel,
wherein the first pattern is a pattern in which a brightness of the first color of the first pixel and a brightness of the first color of the second pixel are same, a light amount ratio of the 1-1 sub-pixel and the 1-2 sub-pixel is 1:0, and a light amount ratio of the 2-1 sub-pixel and the 2-2 sub-pixel is 0:1, and
the second pattern is a pattern in which the brightness of the first color of the first pixel and the brightness of the first color of the second pixel are the same, the light amount ratio of the 1-1 sub-pixel and the 1-2 sub-pixel is 0:1, and the light amount ratio of the 2-1 sub-pixel and the 2-2 sub-pixel is 1:0.

14. A tiling display device comprising:
a first pixel including a 1-1 sub-pixel and a 1-2 sub-pixel configured to emit light in a wavelength band of a same color; and
a second pixel spaced apart from the first pixel and including a 2-1 sub-pixel and a 2-2 sub-pixel configured to emit light in a wavelength band of the same color,
wherein in operation a brightness of the first color of the first pixel is same as a brightness of the first color of the second pixel, and
the 1-1 sub-pixel, the 1-2 sub-pixel, and the 2-1 sub-pixel are turned on, and the 2-2 sub-pixel is turned off.

15. The tiling display device of claim 14, wherein in operation, the light amount ratio of the 1-1 sub-pixel and the 1-2 sub-pixel is in a range of 1:0.1 to 0.1:1.

16. The tiling display device of claim 14, further comprising:
a first pixel block including the first pixel; and
a second pixel block including the second pixel spaced apart from the first pixel in a first direction and neighboring to the first pixel,
wherein a light amount ratio of the 2-1 sub-pixel and the 2-2 sub-pixel is 1:0.

17. The tiling display device of claim 16, wherein an absolute value of a difference between a peak wavelength for the first color of any one of the 1-1 sub-pixel and the 1-2 sub-pixel and a peak wavelength for the first color of the 2-1 sub-pixel is equal to or larger than 0 nm and equal to or less than 5 nm.

18. The tiling display device of claim 17, wherein a luminous intensity distribution for the first color of the first pixel differs from a luminous intensity distribution for the first color of the 1-1 sub-pixel or a luminous intensity distribution for the first color of the 1-2 sub-pixel.

19. A tiling display device comprising:
a first pixel including a 1-1 sub-pixel and a 1-2 sub-pixel configured to emit light in a wavelength band of a same color; and
a second pixel spaced apart from the first pixel and including a 2-1 sub-pixel and a 2-2 sub-pixel configured to emit light in a wavelength band of the same color,
wherein in operation, a brightness of the first color of the first pixel is same as a brightness of the first color of the second pixel, and
the 1-1 sub-pixel, the 1-2 sub-pixel, the 2-1 sub-pixel, and the 2-2 sub-pixel are turned on.

20. The tiling display device of claim 19, wherein the light amount ratio of the 1-1 sub-pixel and the 1-2 sub-pixel is in a range of 1:0.1 to 0.1:1, and the light amount ratio of the 2-1 sub-pixel and the 2-2 sub-pixel is in a range of 1:0.1 to 0.1:1.

21. The tiling display device of claim 19, further comprising:
a first pixel block including the first pixel; and
a second pixel block including the second pixel spaced apart from the first pixel in a first direction and neighboring to the first pixel.

22. The tiling display device of claim 21, wherein a light amount ratio of the 1-1 sub-pixel and the 1-2 sub-pixel is same as a light amount ratio of the 2-1 sub-pixel and the 2-2 sub-pixel.

23. The tiling display device of claim 22, wherein a light amount of the 1-1 sub-pixel is same as a light amount of the 1-2 sub-pixel.

24. A display device comprising:
a plurality of pixels disposed on a display panel, the plurality of pixels including a first pixel adjacent to a second pixel, and a third pixel adjacent to a fourth pixel, the first pixel is configured to emit a first color light with a first brightness, the second pixel is configured to emit the first color light with a second brightness, the third pixel is configured to emit the first color light with a third brightness, and the fourth pixel is configured to emit the first color light with a fourth brightness,
wherein a first distance between the first pixel and the second pixel is different from a second distance between the third pixel and the fourth pixel; and
wherein a first sum of the first brightness and the second brightness is different from a second sum of the third brightness and the fourth brightness.

25. The display device of claim 24, wherein the first distance is larger than the second distance and the first sum id greater than the second sum.
